(19) United States
(12) Patent Application Publication
(10) Pub. No.: US 2023/0115307 A1
(43) Pub. Date: Apr. 13, 2023

(54) BURIED WORD LINE STRUCTURE AND METHOD FOR MANUFACTURING SAME, AND DYNAMIC RANDOM ACCESS MEMORY

(71) Applicant: CHANGXIN MEMORY TECHNOLOGIES, INC., Hefei City, Anhui (CN)

(72) Inventors: Yong LU, Hefei City, Anhui (CN); Hongkun SHEN, Hefei City, Anhui (CN); Gongyi WU, Hefei City, Anhui (CN)

(21) Appl. No.: 17/441,666

(22) PCT Filed: Jun. 30, 2021
(86) PCT No.: PCT/CN2021/103882

§ 371 Date: Sep. 21, 2021

(30) Foreign Application Priority Data
Oct. 22, 2020 (CN) 202011151832.5

(51) Int. Cl. H10B 12/00

(52) U.S. Cl. CPC H01L 27/10805; H01L 27/10891

(57) ABSTRACT

The present disclosure provides a buried word line structure and a method for manufacturing the same, and a dynamic random access memory. The buried word line structure includes: a semiconductor substrate, word line trenches and word line structures. The semiconductor substrate is provided with active areas and shallow trench isolations, and the shallow trench isolations isolate the active areas. The word line trenches pass through the active areas along a first direction. The word line structures are disposed in the word line trenches. The word line structures include: a high dielectric constant dielectric layer covering inner surfaces of the word line trenches; a polysilicon layer covering the high dielectric constant dielectric layer; a work function layer covering the polysilicon layer; and a word line metal layer filled on a side of the work function layer away from the polysilicon layer.

### CROSS-REFERENCE TO RELATED APPLICATIONS

The present disclosure is a national stage entry of International Application No. PCT/CN2021/103882, filed on Jun. 30, 2021, which claims the priority to Chinese Patent Application 202011151832.5, titled “BURIED WORD LINE STRUCTURE AND METHOD FOR MANUFACTURING SAME, AND DYNAMIC RANDOM ACCESS MEMORY” and filed on Oct. 22, 2020. The entire contents of International Application No. PCT/CN2021/103882 and Chinese Patent Application 202011151832.5 are incorporated herein by reference.

### TECHNICAL FIELD

The present disclosure relates to, but is not limited to, a buried word line structure and a method for manufacturing the same, and a dynamic random access memory.

### BACKGROUND

A Dynamic Random Access Memory (DRAM) is a semiconductor device commonly used in electronic equipment such as a computer, and includes a memory cell array for storing data and a circuit at the periphery of the memory cell array. Each memory cell includes a transistor (word line), a bit line, and a capacitor. The word line voltage on the transistor (word line) can control the on and off of the transistor, so that the data information stored in the capacitor can be read through the bit line, or the data information can be written into the capacitor.

With the continuous development of technology, transistors are getting smaller and smaller, and channel electric field intensities of Metal Oxide Semiconductors (MOS) continue to increase. As the process size node of the DRAM drops to 20 nm and below, the energy density per unit area of MOS devices increases significantly, accompanied by the problems of prominent leakage and power consumption increase.

### SUMMARY

The following is the summary of subject matters detailed in the present disclosure. The summary is not intended to limit the protection scope of the claims.

The present disclosure provides a buried word line structure and a method for manufacturing the same, and a dynamic random access memory.

The first aspect of the present disclosure provides a buried word line structure, including a semiconductor substrate, word line trenches and word line structures. The semiconductor substrate is provided with active areas and shallow trench isolations, and the shallow trench isolations isolate the active areas. The word line trenches pass through the active areas along a first direction. The word line structures are disposed in the word line trenches. The word line structures include: a high dielectric constant dielectric layer covering inner surfaces of the word line trenches; a polysilicon layer covering the high dielectric constant dielectric layer; a work function layer covering the polysilicon layer; and a word line metal layer filled on a side of the work function layer away from the polysilicon layer.

The second aspect of the present disclosure provides a dynamic random access memory, including the buried word line structure described in the first aspect.

The third aspect of the present disclosure provides a method for manufacturing a buried word line structure, used to manufacture the buried word line structure described in the first aspect, the method for manufacturing the buried word line structure including: providing a semiconductor substrate, and forming active areas and shallow trench isolations on the semiconductor substrate, the shallow trench isolations isolating the active areas; forming word line trenches in the active areas, the word line trenches passing through the active areas along a first direction; forming a high dielectric constant dielectric layer on inner surfaces of the word line trenches; forming a polysilicon layer on the high dielectric constant dielectric layer; depositing a work function layer on the polysilicon layer; filling the word line trenches with a word line metal layer to form word line structures in the word line trenches; and etching the word line structures back.

Other aspects will be apparent upon reading and understanding the accompanying drawings and detailed descriptions.

### BRIEF DESCRIPTION OF THE DRAWINGS

The accompanying drawings incorporated into the description and constituting a part of the description illustrate the embodiments of the present disclosure, and are used together with the description to explain the principles of the embodiments of the present disclosure. In these drawings, similar reference numerals are used to indicate similar elements. The drawings in the following description are some embodiments of the present disclosure, but not all embodiments. For those skilled in the art, other drawings can be obtained from these drawings without any creative efforts.

FIG. 1 is a top view of a buried word line structure in an exemplary embodiment of the present disclosure;

FIG. 2 is a top view of a semiconductor substrate in an exemplary embodiment of the present disclosure;

FIG. 3 is a cross-sectional view taken along B-B in FIG. 2;

FIG. 4 is a schematic diagram of forming word line trenches in an exemplary embodiment of the present disclosure;

FIG. 5 is a schematic diagram of forming a high dielectric constant dielectric layer in an exemplary embodiment of the present disclosure;

FIG. 6 is a schematic diagram of forming polysilicon in an exemplary embodiment of the present disclosure;

FIG. 7 is a schematic diagram of forming a polysilicon layer in an exemplary embodiment of the present disclosure;

FIG. 8 is a schematic diagram of forming a work function layer in an exemplary embodiment of the present disclosure;

FIG. 9 is a schematic diagram of forming word line structures after a word line metal layer is filled in an exemplary embodiment of the present disclosure;

FIG. 10 is a schematic diagram of etching the word line structures back in an exemplary embodiment of the present disclosure;

FIG. 11 is a cross-sectional view taken along A-A in FIG. 1, showing a buried word line structure formed after the word line structures are etched back and a barrier layer is filled;

FIG. 12 is a flowchart of a method for manufacturing a buried word line structure of the present disclosure.

### Reference Numerals

1: semiconductor substrate; 11: active area; 12: shallow trench isolation; 13: first hard mask layer; 14: word line trench; 2: word line structure; 21: high dielectric constant dielectric layer; 23: polysilicon layer; 25: work function layer; 27: word line metal layer; 3: barrier layer; D1: depth of the word line trench; W1: cross-sectional width of the word line trench; F1: first direction; F2: second direction; d1: first depth.

### DETAILED DESCRIPTION

A clear and complete description will be made to the technical solutions in the embodiments of the present disclosure below in combination with the drawings in the embodiments of the present disclosure. Apparently, the embodiments described are part of the embodiments of the present disclosure, not all of them. All other embodiments obtained by those skilled in the art based on the embodiments of the present disclosure without any creative efforts shall fall within the protection scope of the present disclosure. It should be noted that the embodiments in the present disclosure and the features in the embodiments can be combined with each other on a non-conflict basis.

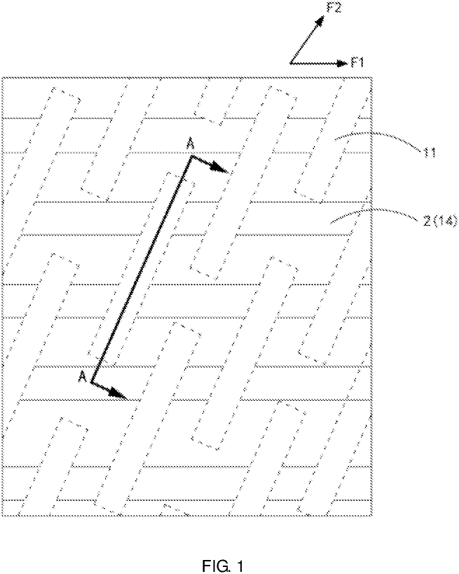

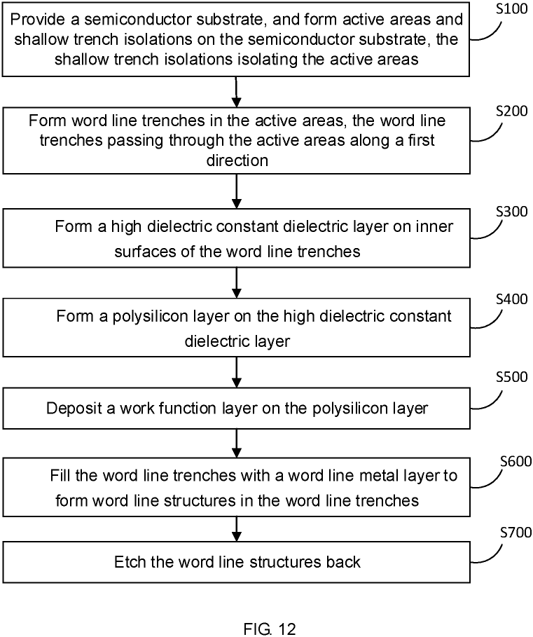

Refer to FIGS. 1 to 11, which respectively show schematic structure diagrams of a buried word line structure in the present disclosure during manufacturing, and FIG. 12 shows a flowchart of a method for manufacturing a buried word line structure in the present disclosure.

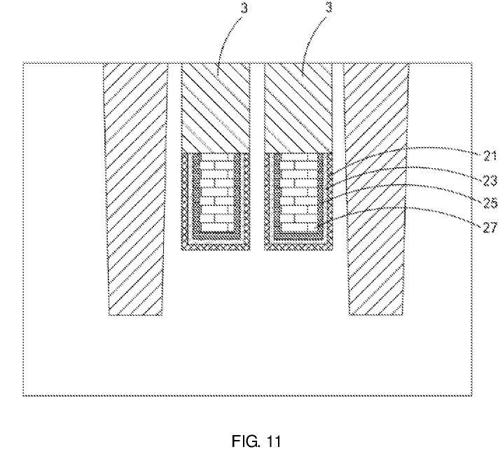

As shown in FIGS. 1 and 11, FIG. 1 shows a top view of a buried word line structure in an embodiment of the present disclosure, and FIG. 11 shows a cross-sectional view taken along A-A in FIG. 1. As shown in the figures, the buried word line structure includes: a semiconductor substrate 1, word line trenches 14 and word line structures 2. The semiconductor substrate 1 is provided with active areas 11 and shallow trench isolations 12, and the shallow trench isolations 12 isolate the active areas 11. The word line trenches 14 pass through the active areas 11 along a first direction F1. The word line structures 2 are disposed in the word line trenches. The word line structures 2 include: a high dielectric constant dielectric layer 21 covering inner surfaces of the word line trenches 14; a polysilicon layer 23 covering the high dielectric constant dielectric layer 21; a work function layer 25 covering the polysilicon layer 23; and a word line metal layer 27 filled on a side of the work function layer 25 away from the polysilicon layer 23.

Since the word line metal layer 27 is covered with the polysilicon layer 23 and the high dielectric constant dielectric layer 21 in the word line structures 2, the gate-induced leakage can be effectively reduced, and the power consumption can be significantly reduced.

The buried word line structure of the present disclosure will be described in detail below.

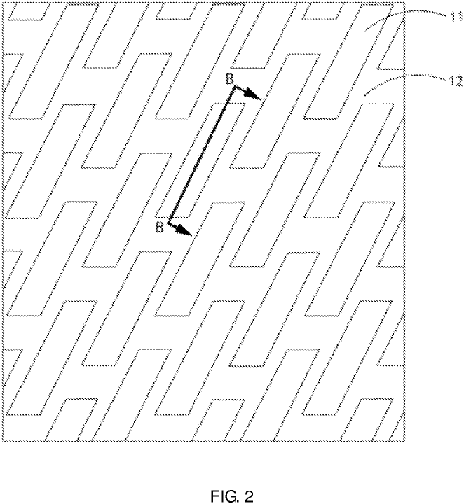

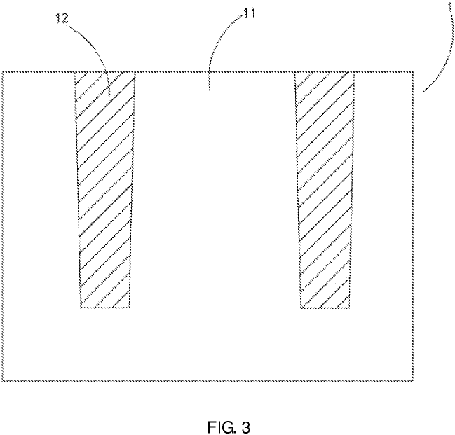

As shown in FIGS. 2 and 3, the semiconductor substrate 1 of the embodiment of the present disclosure has active areas (AA) 11 and shallow trench isolations (STI) 12. The shallow trench isolations 12 define a plurality of active areas 11, that is, the adjacent active areas 11 are separated by the shallow trench isolations 12 in an insulating manner.

The semiconductor substrate 1 of the embodiment of the present disclosure may include a substrate, and the substrate may be made of silicon, silicon carbide, silicon nitride, silicon-on-insulator, stacked silicon-on-insulator, stacked silicon-germanium-on-insulator, lamellar silicon germanium-on-insulator or lamellar germanium-on-insulator, etc.

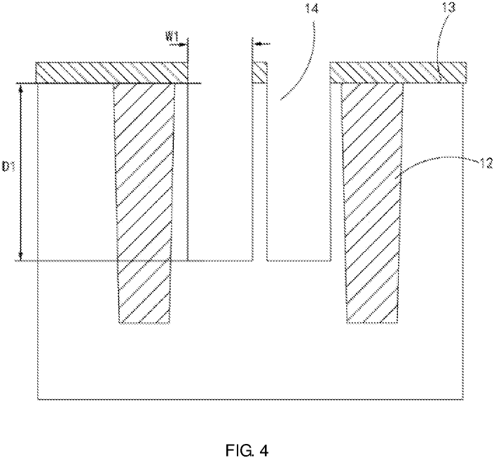

In an exemplary embodiment, as shown in FIGS. 1 and 4, the word line trenches 14 are formed in the semiconductor substrate 1 and pass through the active areas 11 along the first direction F1. The following mainly refers to the word line trenches 14 passing through the active areas 11. The depths D1 of the word line trenches 14 are 50 to 300 nm, for example, 80 nm, 100 nm, 120 nm, 150 nm, 180 nm, 200 nm, 240 nm, or 280 nm, and the widths W1 of cross-sections of the word line trenches 14 are 20 to 100 nm, for example, 40 nm, 50 nm, 70 nm, 80 nm, or 90 nm, which can be set by those skilled in the art according to the actual situation and will not be specifically limited here. The number of word line trenches 14 in each active area 11 may be one, two, three, or four, which will not be specifically limited here.

As shown in FIG. 11, the buried word line structure further includes: a barrier layer 3 filled in the word line trenches 14 and located on the word line structures 2, the upper surface of the barrier layer 3 being flush with the upper surface of the semiconductor substrate 1.

It should be noted that “upper” and “lower” in the embodiments of the present disclosure are technical terms indicating the relative positional relationship of layers. For example, as shown in FIG. 11, the openings of the word line trenches 14 face upward, and the word line structures 2 are buried under the barrier layer 3. The technical terms are only used to more clearly explain the relative positional relationship of various components in the semiconductor device, and do not have limited meanings.

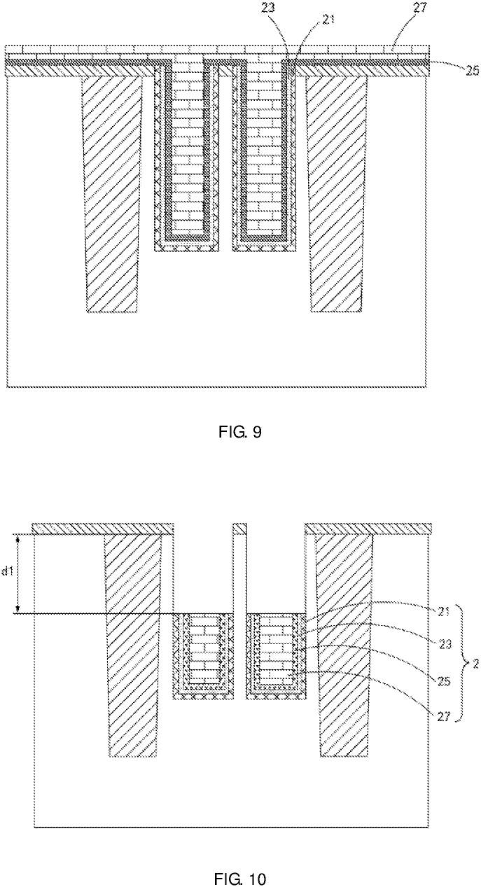

In an exemplary embodiment, as shown in FIG. 10, the word line structures 2 are filled from a first depth d1 of the word line trenches 14 to bottom ends of the word line trenches 14, which can be understood as the word line trenches 14 are divided into two parts, the first parts are from top ends of the word line trenches 14 to the first depth d1, the second parts are from the first depth d1 to the bottom ends of the word line trenches 14, and the word line structures 2 are filled in the second parts. The first depth d1 may be 20 to 150 nm, for example, 40 nm, 60 nm, 80 nm, 100 nm, or 120 nm, which will not be specifically limited here.

In an exemplary embodiment, as shown in FIG. 10, the word line structures 2 include: a high dielectric constant dielectric layer 21, a polysilicon layer 23, a work function layer 25 and a word line metal layer 27 sequentially laminated to cover the inner surfaces of the word line trenches 14.

As shown in FIG. 10, the high dielectric constant dielectric layer 21 covers the inner surfaces of the word line trenches 14, for example, covers the inner surfaces of the second parts of the word line trenches 14. The inner surfaces of the word line trenches 14 include inner side wall surfaces and bottom surfaces. The high dielectric constant dielectric layer 21 may be formed on the inner surfaces of the word line trenches 14 by deposition. In an exemplary embodiment, the dielectric constant of the high dielectric constant dielectric layer 21 may be greater than 4, and the high dielectric constant dielectric layer 21 may be made of hafnium oxide (HfO₂), hafnium silicate oxynitride (HfSiO₄), aluminum oxide (Al₂O₃), zirconium oxide (ZrO₂), hafnium zirconate (HfZrO₄), yttrium oxide (Y₂O₃), strontium titanate (SrTiO₃), or lead zirconate titanate (PbZrxTi1-xO₃), etc., which can be set by those skilled in the art according to actual needs and is not specifically limited here.

In an exemplary embodiment, the high dielectric constant dielectric layer 21 has a thickness of 1 to 10 nm, for example, 3 nm, 5 nm, 7 nm, 8 nm, or 9 nm, and a person skilled in the art can control the thickness of the high dielectric constant dielectric layer 21 through a control process according to actual needs, which will not be specifically limited here. Through the high dielectric constant dielectric layer 21, the leakage can be reduced by 10 times or more, and the power consumption can be significantly reduced.

Continuing to refer to FIG. 10, the polysilicon layer 23 in the word line structures 2 covers the high dielectric constant dielectric layer 21. For example, when the semiconductor substrate 1 is N-type, the polysilicon layer 23 is P-type, and when the semiconductor substrate is P-type, the polysilicon layer 23 is N-type, that is, the types of the semiconductor substrate 1 and the polysilicon layer 23 may be opposite. As such, the polysilicon layer 23 can adjust a work function together with the work function layer 25 according to the type of doped ions and the amount of doping, thereby effectively reducing leakage current. The P-type or N-type polysilicon layer 23 is formed by doping. Therefore, as shown in FIG. 6, during the formation of the polysilicon layer 23 in a furnace tube, while the polysilicon layer 23 is grown or deposited on the high dielectric constant dielectric layer 21, the polysilicon layer 23 is doped to form a P-type or N-type polysilicon material. The P-type and N-type doping technology is a well-known technology in the art, can be known by those skilled in the art based on the existing technology and will not be explained in detail here.

In an exemplary embodiment, as shown in FIGS. 8 and 10, the work function layer 25 covers the polysilicon layer 23. The work function layer 25 may be made of titanium nitride (TiN). The material of the work function layer 25 can increase the adhesion between the buried word line metal layer 27 and a gate dielectric layer and avoid leakage. The work function layer 25 may have a thickness of 2 to 7 nm, for example, 3 nm, 4 nm, 5 nm or 6 nm, which can be set by those skilled in the art according to actual needs and will not be specifically limited here.

As shown in FIG. 10, the word line metal layer 27 is filled on a side of the work function layer 25 away from the polysilicon layer 23. That is, it is filled in the remaining spaces of the second parts of the word line trenches 14. Since the side walls and bottom walls of the second parts of the word line trenches 14 are respectively covered with the high dielectric constant dielectric layer 21, the polysilicon layer 23 and the work function layer 25 in sequence, 2 times the sum of the thicknesses of the layers is still less than the cross-sectional widths W1 of the word line trenches 14, the outermost work function layer 25 forms two opposite sides, and the word line metal layer 27 is filled in spaces of the two opposite sides of the work function layer 25, so that the second parts of the word line trenches 14 are completely filled with the word line structures 2 formed by the layers.

In an exemplary embodiment, as shown in FIG. 11, the barrier layer 3 is filled from the top ends of the word line trenches 14 to the first depth d1, that is, the filling depth of the barrier layer 3 in the word line trenches is the first depth d1, and the barrier layer 3 is located on the word line structures 2. That is, the barrier layer 3 is filled in the first parts of the word line trenches 14, to bury the word line structures 2 in the word line trenches 14, so as to form a buried word line structure. In addition, the upper surface of the barrier layer 3 is flush with the upper surface of the semiconductor substrate 1.

In an exemplary embodiment, the barrier layer 3 may be made of SiN. The barrier layer 3 is deposited on the surface of the semiconductor substrate 1 and in the first parts of the word line trenches 14 by chemical vapor deposition (CVD), and finally undergoes chemical mechanical polishing (CMP) to obtain a flat surface without scratches and impurity pollution.

Based on the above, in the buried word line structure in the embodiment of the present disclosure, since the word line metal layer 27 is covered with the polysilicon layer 23 and the high dielectric constant dielectric layer 21 in the word line structures 2, the gate-induced leakage can be effectively reduced, and the power consumption can be significantly reduced.

According to another aspect of the present disclosure, an embodiment of the present disclosure provides a dynamic random access memory, including the buried word line structure in any of the above-mentioned embodiments. The dynamic random access memory includes: a memory cell array and a circuit located at the periphery of the memory cell array. Each memory cell includes the buried word line structure in the above-mentioned embodiment, a bit line, and a capacitor. Since the structure and connection relationship of the bit line and the capacitor are well-known technologies in the art, and the buried word line structure is described in detail in the above embodiments, details are not described herein again.

The dynamic random access memory provided by the embodiment of the present disclosure is provided with the above-mentioned buried word line structure, which effectively reduces gate-induced leakage, reduces power consumption, and improves performance.

According to another aspect of the present disclosure, an embodiment of the present disclosure provides a method for manufacturing a buried word line structure. As shown in FIG. 12, a flowchart of a method for manufacturing a buried word line structure in the present disclosure is shown. As shown in the figure, the method for manufacturing a buried word line structure includes:
Step S100: providing a semiconductor substrate, and forming active areas and shallow trench isolations on the semiconductor substrate, the shallow trench isolations isolating the active areas;
Step S200: forming word line trenches in the active areas, the word line trenches passing through the active areas along a first direction;
Step S300: forming a high dielectric constant dielectric layer on inner surfaces of the word line trenches;
Step S400: forming a polysilicon layer on the high dielectric constant dielectric layer;
Step S500: depositing a work function layer on the polysilicon layer;
Step S600: filling the word line trenches with a word line metal layer to form word line structures in the word line trenches;
Step S700: etching the word line structures back.

Refer to FIGS. 2 to 11, which show schematic diagrams of a semiconductor substrate and a buried word line structure in different steps. The manufacturing method will be described in detail below.

As shown in FIGS. 2 and 3, in step S100, a semiconductor substrate 1 is provided, and active areas 11 and shallow trench isolations 12 are formed on the semiconductor substrate 1, the shallow trench isolations 12 isolating the active areas 11.

For example, when the buried word line structure is manufactured, the semiconductor substrate 1 may be treated in advance to form the active areas 11 and the shallow trench isolations 12 on the semiconductor substrate 1. The shallow trench isolations 12 are configured to separate adjacent active areas 11 and insulate the adjacent active areas 11 from each other. As shown in FIG. 2, a plurality of active areas 11 are arranged in parallel with each other, and each active area 11 extends in a second direction F2 on the semiconductor substrate 1.

As shown in FIG. 4, in step S200, word line trenches 14 are formed in the active areas 11, the word line trenches 14 passing through the active areas 11 along a first direction F1.

In an exemplary embodiment, a first hard mask layer is first formed on the semiconductor substrate 1, and a first pattern is formed on the first hard mask layer. Based on the first pattern, the semiconductor substrate 1 is etched to form the word line trenches 14. The semiconductor substrate 1 may be etched by chemical etching, photolithography, etc. Etching parameters are controlled, for example, when chemical etching is used, the dosage and concentration of the etching reagent are controlled, so as to realize the word line trenches 14 with specific depths and cross-sectional widths.

As shown in FIG. 1, the first direction F1 and the second direction F2 have a certain angle, and are not perpendicular.

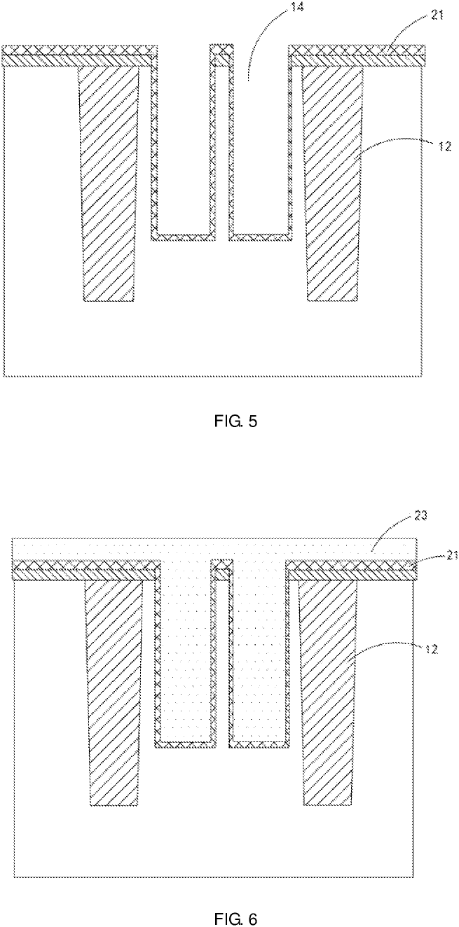

As shown in FIG. 5, in step S300, a continuous high dielectric constant dielectric layer 21 is formed on inner surfaces of the word line trenches 14.

For example, the material of the high dielectric constant dielectric layer 21 may be deposited on the inner surfaces of the word line trenches 14 by Atomic Layer Deposition (ALD). The high dielectric constant dielectric layer 21 may have a thickness of 2 to 10 nm. The high dielectric constant dielectric layer 21 is uniformly and continuously deposited on the inner side wall surfaces and bottom surfaces of the word line trenches 14. In fact, as shown in FIG. 5, the deposition is carried out on the entire semiconductor substrate 1 during manufacturing. Therefore, the high dielectric constant dielectric layer 21 is not only deposited in the word line trenches 14, but also deposited on the surface of the semiconductor substrate 1 at the periphery of the trenches. The embodiment of the present disclosure focuses on forming a buried word line structure in the word line trenches 14, and simply describes the formation layers on the periphery of the word line trenches 14.

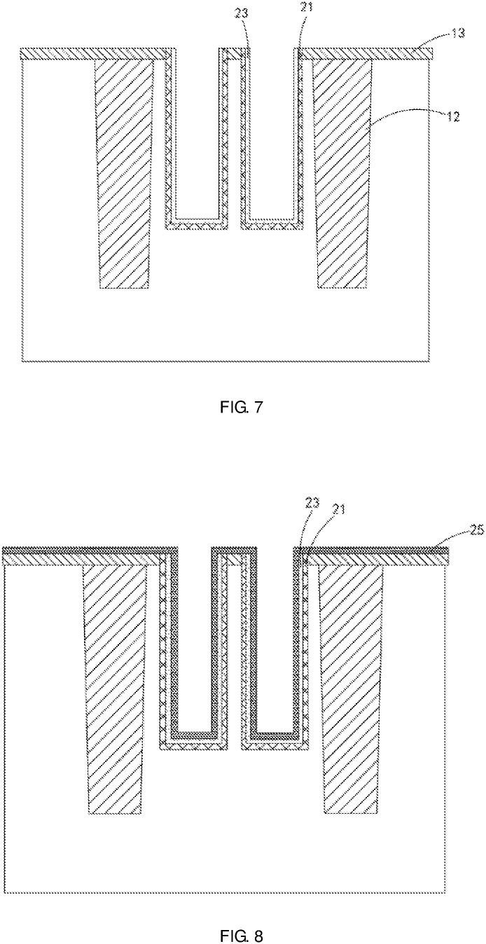

As shown in FIGS. 6 and 7, in step S400, a polysilicon layer 23 is formed on the high dielectric constant dielectric layer 21.

In an exemplary embodiment, as shown in FIG. 6, polysilicon may be simultaneously deposited and doped in the word line trenches 14 to which the high dielectric constant dielectric layer 21 is attached, to form polysilicon, and the polysilicon is filled in the word line trenches 14. For example, the doped polysilicon may be prepared in a tube furnace. The type of the polysilicon is opposite to the type of the semiconductor substrate 1. For example, when the semiconductor substrate 1 is N-type, the polysilicon may be P-type, and when the semiconductor substrate 1 is P-type, the polysilicon may be N-type. In this way, leakage current can be further effectively reduced. Of course, according to actual needs, the types of the semiconductor substrate base 1 and the polysilicon may also be the same, which will not be specifically limited here.

After that, a second hard mask layer is formed on the semiconductor substrate 1, and a second pattern is formed on the second hard mask layer. As shown in FIG. 7, part of the polysilicon is etched based on the second pattern to form a polysilicon layer 23. Etching part of the polysilicon is to etch the middle parts of the polysilicon filled in the word line trenches 14, so that recesses are formed in the word line trenches 14 again to accommodate the subsequent growth layer, that is, the inner surfaces of the recesses are the polysilicon layer 23. Finally, the polysilicon layer 23 covers the high dielectric constant dielectric layer 21, the polysilicon layer 23 has a uniform thickness, the depths of the recesses formed again in the word line trenches 14 are 20 to 50 nm, for example, 30 nm, 35 nm or 40 nm, and the widths of the cross-sections of the recesses are 20 to 50 nm, for example, 25 nm, 30 nm or 40 nm. The widths of the cross-sections may be understood as the distance between opposite parts of the polysilicon layer 23 in the vertical direction. A person skilled in the art can select the sizes according to the actual situation, which is not specifically limited here.

As shown in FIG. 8, in step S500, a work function layer 25 is deposited on the polysilicon layer 23.

For example, a work function layer 25 with uniform thickness may be deposited on the polysilicon layer 23 by atomic layer deposition technology. The work function layer 25 may be made of TiN, which can increase the adhesion between the buried word line metal layer 27 and the dielectric layer and effectively avoid leakage.

As shown in FIG. 9, in step S600, the word line trenches 14 are filled with a word line metal layer 27 to form word line structures 2 in the word line trenches 14.

For example, the word line metal layer 27 may be deposited by chemical vapor deposition technology. The word line metal layer 27 is filled in the word line trenches 14 completely, so that the spaces between the work function layers 25 formed in the previous step is fully filled. After the word line metal layer 27 is formed, the word line metal layer 27 attached to the semiconductor substrate 1 may be further polished by chemical mechanical polishing, so that its surface is more smooth. The metal of the word line metal layer 27 may be tungsten (W).

At this time, the word line trenches 14 are fully filled with the word line structures 2. The word line structures 2 include the high dielectric constant dielectric layer 21, the polysilicon layer 23, the work function layer 25 and the word line metal layer 27 formed in the above steps.

As shown in FIG. 10, in step S700, the word line structures 2 are etched back.

In an exemplary embodiment, the word line structures 2 are etched back to the first depth d1 to further form sub-trenches. The first depth d1 may be 20 to 150 nm. The sub-trenches are equivalent to the first parts of the word line trenches 14 in the embodiment of the buried word line structure. The sub-trenches are formed in order to be able to deposit a barrier layer 3 above the word line structures 2 to bury the word line structures 2.

The word line structures 2 may be etched back by dry etching, and then the work function layer 25 remaining on the inner walls of the word line trenches 14 after the dry etching is removed by wet etching. Finally, the sub-trenches are formed.

As shown in FIG. 11, the method for manufacturing a buried word line structure according to the embodiment of the present disclosure further includes:

Step S800: filling the word line trenches with a barrier layer, the barrier layer being located on the word line structures etched back, and the upper surface of the barrier layer being flush with the upper surface of the semiconductor substrate, to form a buried word line structure.

In an exemplary embodiment, the barrier layer 3 is filled in the sub-trenches of the word line trenches 14. The barrier layer 3 may be deposited by chemical vapor deposition technology. The barrier layer 3 may be made of SiN. The barrier layer 3 is filled in the sub-trenches and located on the word line structures 2 to bury the word line structures 2, so as to form a buried word line structure. After the barrier layer 3 is formed, the barrier layer 3 may be polished and masked by chemical mechanical polishing, so that its surface is more smooth, which is beneficial to the application of the structure.

In addition, it should be noted that, since the embodiment of the present disclosure focuses on forming a buried word line structure in the word line trenches 14, the description of a film on the semiconductor substrate 1 outside the word line trenches 14 is omitted in the above embodiment. In fact, in the above manufacturing process, it is impossible to deposit a single word line trench 14, but the entire semiconductor substrate 1. Therefore, the high dielectric constant dielectric layer 21, the polysilicon layer 23, the work function layer 25, the word line metal layer 27, and the barrier layer 3 in the above embodiment are not only formed in the word line trenches 14, but also formed on the surface of the semiconductor substrate 1 on the periphery of the word line trenches 14, and only the peripheral film is removed in the subsequent process.

Based on the above, the method for manufacturing a buried word line structure according to the embodiment of the present disclosure is simple, and can manufacture a buried word line structure that can effectively avoid leakage and reduce power consumption. After the buried word line structure is applied to the DRAM, gate-induced leakage of the DRAM is effectively reduced, and the performance of the DRAM can be effectively improved.

The embodiments or implementations in this specification are described in a progressive manner, each embodiment focuses on the differences from other embodiments, and the same or similar parts between the various embodiments may be referred to each other.

In the description of this specification, the descriptions with reference to the terms “embodiment”, “exemplary embodiment”, “some implementations”, “schematic implementation”, “example”, etc. mean that specific features, structures, materials or characteristics described in conjunction with the embodiments or examples are included in at least one embodiment or example of the present application.

In this specification, the schematic descriptions of the above terms do not necessarily refer to the same embodiment or example. Moreover, the described specific features, structures, materials or characteristics may be combined in an appropriate manner in any one or more embodiments or examples.

In the description of the present disclosure, it should be noted that the orientations or positional relationships indicated by the terms “center”, “upper”, “lower”, “left”, “right”, “vertical”, “horizontal”, “inner”, “outer”, etc. are based on the orientations or positional relationships shown in the accompanying drawings, and are intended to facilitate the description of the present disclosure and simplify the description only, rather than indicating or implying that the device or element referred to must have a particular orientation or be constructed and operated in a particular orientation, and will not to be interpreted as limiting the present disclosure.

It can be understood that the terms “first”, “second”, etc. used in the present disclosure can be used in the present disclosure to describe various structures, but these structures are not limited by these terms. These terms are only used to distinguish the first structure from another structure.

In one or more drawings, the same elements are represented by similar reference numerals. For the sake of clarity, various parts in the drawings are not drawn to scale. In addition, some well-known parts may not be shown. For the sake of brevity, the structure obtained after several steps can be described in one figure. Many specific details of the present disclosure are described below, such as the structure, material, dimension, treatment process and technology of devices, in order to understand the present disclosure more clearly. However, as those skilled in the art can understand, the present disclosure may not be implemented according to these specific details.

Finally, it should be noted that the above embodiments are merely used to describe, but not to limit, the technical solutions of the present disclosure. Although the present disclosure is described in detail with reference to the above embodiments, those of ordinary skill in the art should understand that various modifications may be made to the technical solutions described in the foregoing embodiments, or equivalent substitutions may be made to some or all technical features thereof, and these modifications or substitutions do not make the essences of the corresponding technical solutions depart from the scope of the technical solutions of the embodiments of the present disclosure.

### INDUSTRIAL APPLICABILITY

In the buried word line structure and the method for manufacturing the same, and the dynamic random access memory provided by the embodiments of the present disclosure, since the word line metal layer is covered with the polysilicon layer and the high dielectric constant dielectric layer in the word line structures, gate-induced leakage can be effectively reduced, and power consumption can be significantly reduced. After the buried word line structure is applied to the DRAM, gate-induced leakage of the DRAM is effectively reduced, and the performance of the DRAM can be effectively improved.

1. A buried word line structure, comprising:
a semiconductor substrate, provided with active areas and shallow trench isolations, the shallow trench isolations isolating the active areas;
word line trenches, passing through the active areas along a first direction; and
word line structures, disposed in the word line trenches, the word line structures comprising:
a high dielectric constant dielectric layer, covering inner surfaces of the word line trenches;
a polysilicon layer, covering the high dielectric constant dielectric layer;
a work function layer, covering the polysilicon layer; and
a word line metal layer, filled on a side of the work function layer away from the polysilicon layer.

2. The buried word line structure according to claim 1, the buried word line structure further comprising: a barrier layer filled in the word line trenches and located on the word line structures, an upper surface of the barrier layer being flush with an upper surface of the semiconductor substrate.

3. The buried word line structure according to claim 2, wherein depths of the word line trenches are 50 to 300 nm and the-widths of cross-sections are 20 to 100 nm.

4. The buried word line structure according to claim 3, wherein a filling depth of the barrier layer in the word line trenches is a first depth, and the first depth is 20 to 150 nm.

5. The buried word line structure according to claim 1, wherein the high dielectric constant dielectric layer has a dielectric constant greater than 4, and is made of one or more of hafnium oxide, hafnium silicate oxynitride, aluminum oxide, zirconium oxide or hafnium zirconate.

6. The buried word line structure according to claim 1, wherein the high dielectric constant dielectric layer has a thickness of 2 to 10 nm.

7. The buried word line structure according to claim 1, wherein the work function layer is made of TiN, and the work function layer has a thickness of 2 to 7 nm.

8. The buried word line structure according to claim 2, wherein the barrier layer is made of SiN.

9. A dynamic random access memory, comprising a buried word line structure, the buried word line structure, comprising:
a semiconductor substrate, provided with active areas and shallow trench isolations, the shallow trench isolations isolating the active areas;
word line trenches, passing through the active areas along a first direction; and
word line structures, disposed in the word line trenches, the word line structures comprising:
a high dielectric constant dielectric layer, covering inner surfaces of the word line trenches;
a polysilicon layer, covering the high dielectric constant dielectric layer;
a work function layer, covering the polysilicon layer; and
a word line metal layer, filled on a side of the work function layer away from the polysilicon layer.

10. A method for manufacturing a buried word line structure, configured to manufacture the buried word line structure according to claim 1, the method for manufacturing the buried word line structure comprising:
providing a semiconductor substrate, and forming active areas and shallow trench isolations on the semiconductor substrate, the shallow trench isolations isolating the active areas;
forming word line trenches in the active areas, the word line trenches passing through the active areas along a first direction;
forming a high dielectric constant dielectric layer on inner surfaces of the word line trenches;
forming a polysilicon layer on the high dielectric constant dielectric layer;
depositing a work function layer on the polysilicon layer;
filling the word line trenches with a word line metal layer to form word line structures in the word line trenches; and
etching the word line structures back.

11. The method for manufacturing the buried word line structure according to claim 10, wherein the forming word line trenches in the active areas comprises:
forming a first hard mask layer on the semiconductor substrate, and forming a first pattern on the first hard mask layer; and
etching the semiconductor substrate based on the first pattern, and form word line trenches.

12. The method for manufacturing the buried word line structure according to claim 10, wherein the forming a polysilicon layer on the high dielectric constant dielectric layer comprises:
simultaneously depositing and doping polysilicon in the word line trenches to which the high dielectric constant dielectric layer is attached, to form polysilicon, and filling the word line trenches with the polysilicon;
forming a second hard mask layer on the semiconductor substrate, and forming a second pattern on the second hard mask layer; and
etching part of the polysilicon based on the second pattern, and forming the polysilicon layer.

13. The method for manufacturing the buried word line structure according to claim 10, wherein the word line structures are etched back by dry etching, and the work function layer remaining on side walls of the word line trenches is removed by wet etching.

14. The method for manufacturing the buried word line structure according to claim 10, the method for manufacturing the buried word line structure further comprises: filling the word line trenches with a barrier layer, the barrier layer being located on the word line structures etched back, and an upper surface of the barrier layer being flush with an upper surface of the semiconductor substrate.

15. The dynamic random access memory according to claim 9, the buried word line structure further comprising: a barrier layer filled in the word line trenches and located on the word line structures, an upper surface of the barrier layer being flush with an upper surface of the semiconductor substrate.

16. The dynamic random access memory according to claim 9, wherein depths of the word line trenches are 50 to 300 nm and widths of cross-sections are 20 to 100 nm.

17. The dynamic random access memory according to claim 15, wherein a filling depth of the barrier layer in the word line trenches is a first depth, and the first depth is 20 to 150 nm.

18. The dynamic random access memory according to claim 9, wherein the high dielectric constant dielectric layer has a dielectric constant greater than 4, and is made of one or more of hafnium oxide, hafnium silicate oxynitride, aluminum oxide, zirconium oxide or hafnium zirconate.

19. The dynamic random access memory according to claim 9, wherein the high dielectric constant dielectric layer has a thickness of 2 to 10 nm.

20. The dynamic random access memory according to claim 9, wherein the work function layer is made of TiN, and the work function layer has a thickness of 2 to 7 nm.
